(19) United States
(12) Patent Application Publication
(10) Pub. No.: US 2026/0129919 A1
(43) Pub. Date: May 7, 2026

(54) GATE STRUCTURE AND MANUFACTURING METHOD THEREOF

(71) Applicant: Winbond Electronics Corp., Taichung City (TW)

(72) Inventors: Po-Yen Hsu, Taichung City (TW); Shih-Ning Tsai, Taichung City (TW); Yu-Chia Tsao, Taichung City (TW); Bo-Lun Wu, Taichung City (TW)

(73) Assignee: Winbond Electronics Corp., Taichung City (TW)

(21) Appl. No.: 19/378,238

(22) Filed: Nov. 3, 2025

(30) Foreign Application Priority Data
Nov. 4, 2024 (TW) 113142159

(51) Int. Cl. H10D 30/68; H10B 41/30; H10D 30/01

(52) U.S. Cl. CPC H10D 30/6891; H10B 41/30; H10D 30/0411

(57) ABSTRACT

Provided are a gate structure and a manufacturing method thereof. The gate structure comprises a gate device, a first spacer, a cap layer, a hard mask layer and a second spacer. The gate device is disposed on a substrate. The first spacer is disposed on a sidewall of the gate device. The cap layer is disposed on a top surface of the gate device. The hard mask layer is disposed on the cap layer. The second spacer is disposed on a sidewall of the hard mask layer, a sidewall of the cap layer, and the first spacer.

### CROSS-REFERENCE TO RELATED APPLICATION

This application claims the priority benefit of Taiwan application serial no. 113142159, filed on November 04, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular, to a gate structure and a manufacturing method thereof.

### Description of Related Art

Generally speaking, after forming the memory cell of the flash memory, the spacer may be formed on the sidewall of the memory cell. In order to increase the data retention capability, a mask material layer may be formed on the memory cell and the spacer, and the mask material layer may be patterned to form a mask pattern connected to the spacer on the memory cell. However, if the position of the mask pattern is shifted, a part of the top surface of the memory cell may be exposed. As a result, contaminants, such as metal ions, in the subsequent processes may enter the memory cell, and the performance and the reliability of the device may be affected.

In addition, during the planarization process after forming the mask material layer, the dishing often occurs on the top surface of the mask material layer, which cannot protect the spacer of the memory cell well, and may cause the spacer of the memory cell to be damaged in the subsequent processes. As a result, the word line leakage current may be occurred during testing or operation of the flash memory.

### SUMMARY

The present invention provides a gate structure and a manufacturing method thereof that addresses issues with mask patterns failing to adequately protect the memory cell or the spacer of the memory cell.

The gate structure of the present invention includes a gate device, a first spacer, a cap layer, a hard mask layer and a second spacer. The gate device is disposed on a substrate. The first spacer is disposed on a sidewall of the gate device. The cap layer is disposed on a top surface of the gate device. The hard mask layer is disposed on the cap layer. The second spacer is disposed on a sidewall of the hard mask layer, a sidewall of the cap layer, and the first spacer.

The manufacturing method of the gate structure of the present invention includes the following steps. A gate device, a cap layer and a hard mask layer are sequentially formed on a substrate. A first spacer is formed on a sidewall of the gate device. A second spacer is formed on a sidewall of the hard mask layer, a sidewall of the cap layer, and the first spacer.

Based on the above, in the gate structure of the present invention, the hard mask layer is disposed on the cap layer and the second spacer is disposed on the sidewalls of the hard mask layer and the cap layer and on the first spacer. Therefore, the cap layer may be protected by the hard mask layer and the second spacer, and the first spacer may also be protected by the second spacer. In this way, contaminants, such as metal ions, may be effectively prevented from entering the gate device through the cap layer or the first spacer in the subsequent processes, and the spacer of the memory cell may be well protected.

### BRIEF DESCRIPTION OF THE DRAWINGS

FIGS. 1A to 1C are schematic cross-sectional views of the manufacturing process of the gate structure of the first embodiment of the present invention.

FIGS. 2A to 2D are schematic cross-sectional views of the manufacturing process of the gate structure of the second embodiment of the present invention.

FIGS. 3A to 3C are schematic cross-sectional views of the manufacturing process of the gate structure of the third embodiment of the present invention.

### DESCRIPTION OF THE EMBODIMENTS

In the following description, when a device is placed "on" another device, the device may be placed directly on the other device, or an intermediate device may be present therebetween.

In the following embodiments, when the gate structure is a portion of the flash memory, such as the NOR flash memory, the gate device may include the tunneling dielectric layer, the floating gate, the inter-gate dielectric layer and the control gate sequentially disposed on the substrate, but the present invention is not limited thereto.

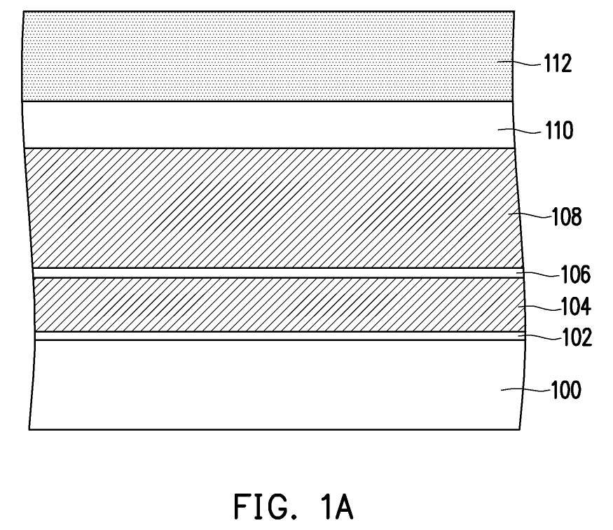

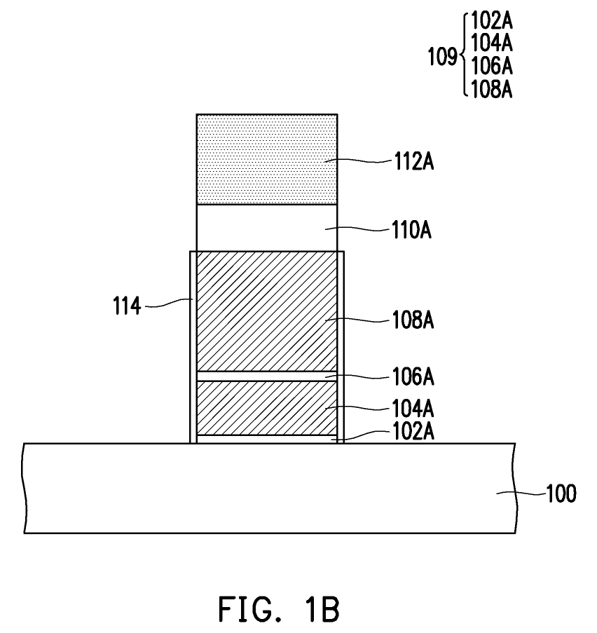

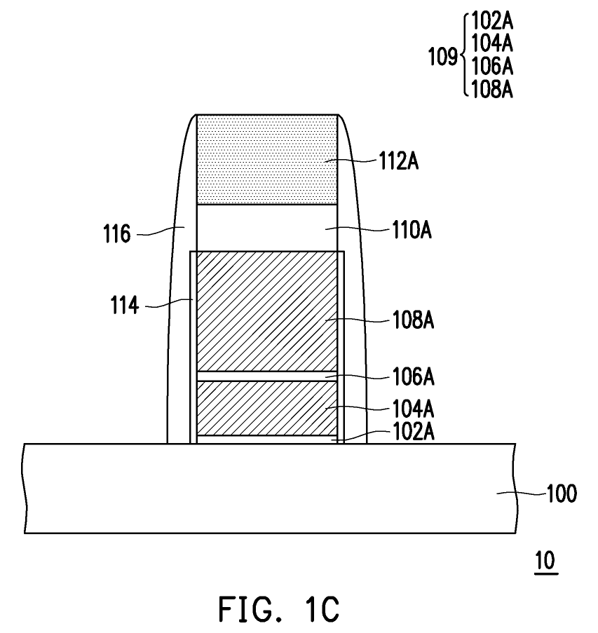

The manufacturing process of the gate structure of the first embodiment of the present invention will be described below with reference to FIGS. 1A to 1C. Referring to FIG. 1A, a dielectric layer 102, a conductive layer 104, a dielectric layer 106, a conductive layer 108, a dielectric layer 110 and a dielectric layer 112 are sequentially formed on a substrate 100.

In the present embodiment, the substrate 100 is, for example, a silicon substrate or a silicon-on-insulator (SOI) substrate, but the present invention is not limited thereto. The dielectric layer 102 is, for example, an oxide layer, which may be formed by, for example, a thermal oxidation process or a chemical vapor deposition process. The dielectric layer 102 may be used to form the tunneling dielectric layer of the gate structure. The conductive layers 104 and 108 are, for example, polysilicon layers, wherein the conductive layer 104 may be used to form the floating gate of the gate structure, and the conductive layer 108 may be used to form the control gate of the gate structure. The dielectric layer 106 is, for example, an oxide layer, which may be used to form an inter-gate dielectric layer of the gate structure. In other embodiments, the dielectric layer 106 may include a composite structure composed of oxide layer/nitride layer/oxide layer (O/N/O). The dielectric layer 110 is, for example, an oxide layer, which may be used to form the cap layer that protects the conductive layer 108. The dielectric layer 112 is, for example, a nitride layer, which may be used to form the hard mask layer. Depending on the functions of the cap layer and the hard mask layer, the material of dielectric layer 110 is different from the material of dielectric layer 112. The conductive layers 104 and 108 and the dielectric layers 106, 110 and 112 may be formed by, for example, a chemical vapor deposition process.

Referring to FIG. 1B, a patterning process is performed to remove a part of the dielectric layer 102, a part of the conductive layer 104, a part of the dielectric layer 106, a part of the conductive layer 108, a part of the dielectric layer 110 and a part of the dielectric layer 112 to form a gate device 109 including a tunneling dielectric layer 102A, a floating gate 104A, an inter-gate dielectric layer 106A and a control gate 108A, as well as a cap layer 110A and a hard mask layer 112A located on the top surface of the gate device 109.

Then, a first spacer 114 is formed on the sidewall of the gate device 109 to protect the gate device 109 from being damaged by the subsequent processes. In the present embodiment, the material of the first spacer 114 is, for example, oxide, and the forming method of the first spacer 114 is, for example, a thermal oxidation process. In addition, in the present embodiment, the top surface of the first spacer 114 is coplanar with the top surface of the control gate 108A, but the present invention is not limited thereto. In other embodiments, the top surface of the first spacer 114 may be coplanar with the top surface of the cap layer 110A, that is, the first spacer 114 may be further formed on the sidewall of the cap layer 110A.

Referring to FIG. 1C, a second spacer 116 is formed on the sidewall of the hard mask layer 112A, the sidewall of the cap layer 110A and the first spacer 114. In the present embodiment, the material of the second spacer 116 is, for example, nitride.

In the gate structure 10 of the present embodiment, the second spacer 116 is disposed on the sidewall of the hard mask layer 112A, the sidewall of the cap layer 110A and the first spacer 114. That is, the second spacer 116 extends from the surface of the substrate 100 to be coplanar with the top surface of the hard mask layer 112A. In addition, the material of the second spacer 116 is different from the material of the cap layer 110A and the material of the first spacer 114. Therefore, the cap layer 110A may be effectively protected by the hard mask layer 112A and the second spacer 116 and the first spacer 114 may also be effectively protected by the second spacer 116 to prevent contaminants, such as metal ions, in the subsequent processes from passing through the cap layer 110A or the first spacer 114 and entering gate device 109.

In addition, in the present embodiment, since the top surface of the second spacer 116 is coplanar with the top surface of the hard mask layer 112A, from the top view on the cap layer 110A and the first spacer 114, the second spacer 116 may have sufficient thickness to block contaminants, such as metal ions, in the subsequent processes from passing through the capping layer 110A or the first spacer 114.

On the other hand, in the present embodiment, during forming the hard mask layer 112A and the cap layer 110A, the hard mask layer 112A may be used as a mask used to define the cap layer 110A. Therefore, after forming the hard mask layer 112A and the cap layer 110A, the sidewall of the hard mask layer 112A can be properly aligned with the sidewall of the cap layer 110A. This alignment minimises the risk of positional deviation of hard mask layer 112A and helps ensure that the top surface of the cap layer 110A remains protected, preventing any potential damage during subsequent processing steps.

In the present embodiment, the second spacer 116 is a single layer, such as a nitride layer, but the present invention is not limited thereto. In other embodiments, the second spacer 116 may be a multi-layer structure composed of at least two selected from the group consisting of an oxide layer, a nitride layer and an air gap. The composition of the multi-layer structure is not limited, as long as the material of the multi-layer structure is enough to protect the cap layer 110A and the first spacer 114.

In the first embodiment, the hard mask layer 112A disposed on the cap layer 110A may be a single layer, but the present invention is not limited thereto. In other embodiments, the hard mask layer disposed on the cap layer 110A may include a first sub-hard mask layer and a second sub-hard mask layer disposed within an inner recess defined by the inner surface of the first sub-hard mask layer, which will be described in detail below.

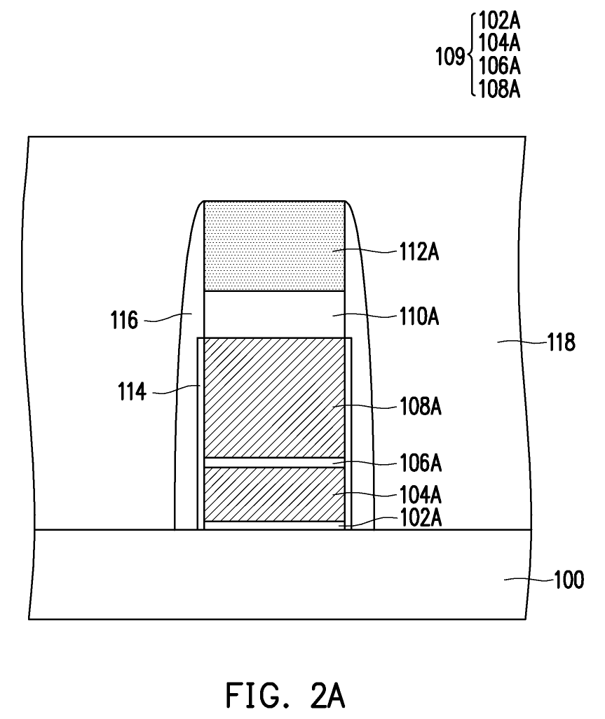

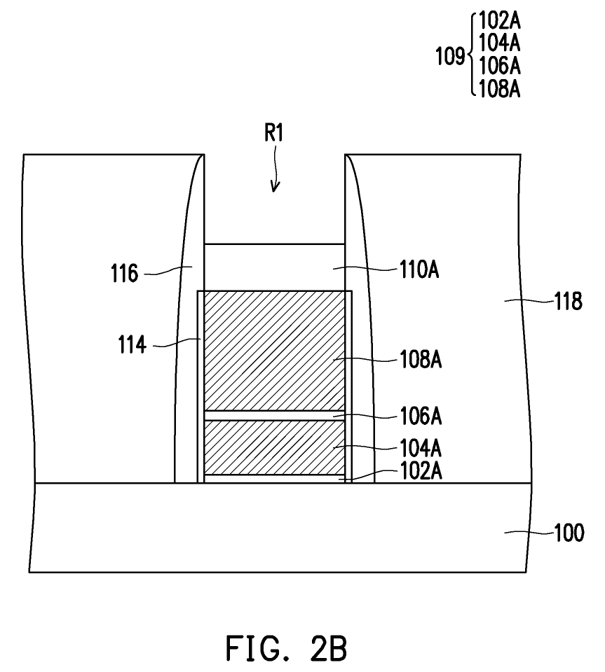

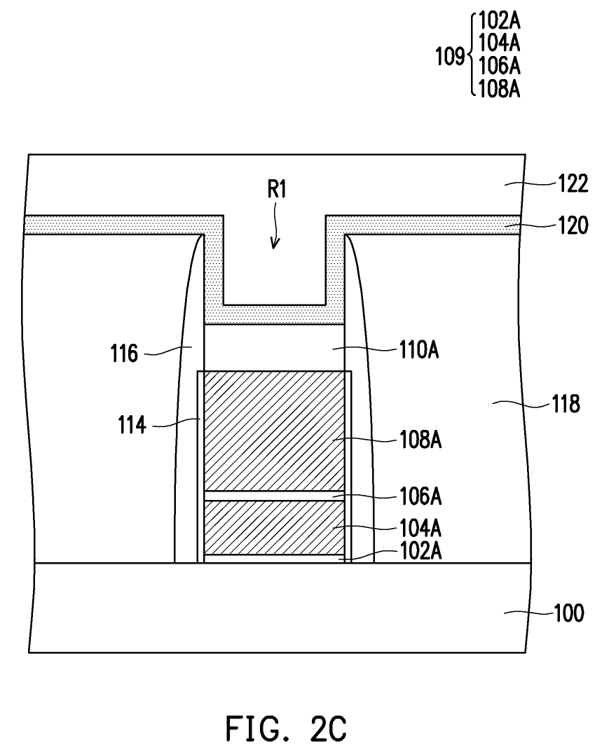

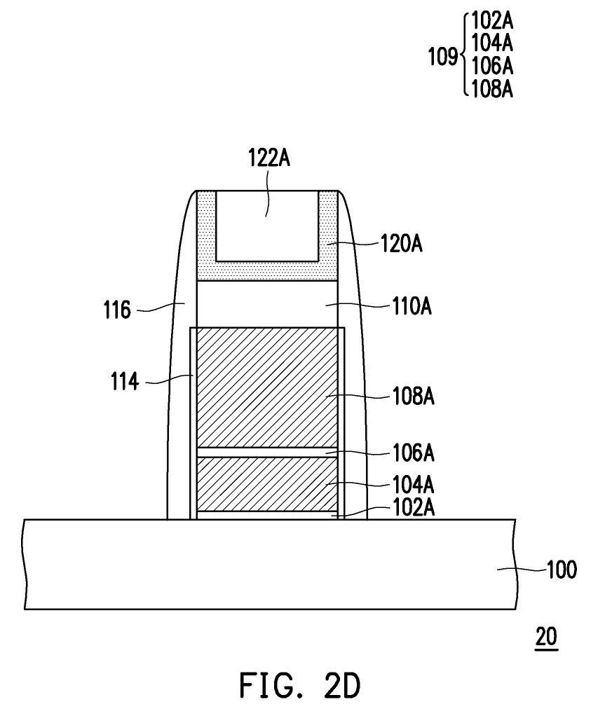

FIGS. 2A to 2D are schematic cross-sectional views of the manufacturing process of the gate structure of the second embodiment of the present invention. In the present embodiment, devices that are the same as those in the first embodiment will be represented by the same reference symbols and will not be described again.

Referring to FIG. 2A, after the gate structure 10 of the first embodiment is formed, a sacrificial layer 118 is formed on the substrate 100. The sacrificial layer 118 covers the second spacer 116 and the hard mask layer 112A. In the present embodiment, the material of the sacrificial layer 118 is, for example, polysilicon, but the present invention is not limited thereto. In other embodiments, the sacrificial layer 118 may be formed of other materials, as long as they have an etching selectivity with respect to the materials of the second spacer 116 and the hard mask layer 112A.

Referring to FIG. 2B, a chemical mechanical polishing (CMP) process may be performed to remove a part of the sacrificial layer 118 until the top surface of the hard mask layer 112A is exposed. Afterwards, the hard mask layer 112A is removed to form a recess R1. That is, in the present embodiment, the recess R1 is defined by the second spacer 116 formed on the sidewall of the hard mask layer 112A and the cap layer 110A located below the hard mask layer 112A.

Referring to FIG. 2C, a first mask material layer 120 is conformally formed on the sacrificial layer 118 and in the recess R1. In the present embodiment, the material of the first mask material layer 120 is different from the material of the cap layer 110A, and may be the same as the material of the second spacer 116. The material of first mask material layer 120 is, for example, nitride. Then, a second mask material layer 122 is formed on the first mask material layer 120, and the second mask material layer 122 fills the recess R1. In the present embodiment, the material of the second mask material layer 122 is different from the material of the first mask material layer 120, and may be the same as the material of the cap layer 110A. The material of the second mask material layer 122 is, for example, oxide.

Afterwards, referring to FIG. 2D, the first mask material layer 120 and the second mask material layer 122 outside the recess R1 are removed, thereby forming the first sub-hard mask layer 120A and the second sub-hard mask layer 122A within the recess R1. The first sub-hard mask layer 120A is located between the second sub-hard mask layer 122A and the sidewall and the bottom surface of the recess R1. In other words, the second sub-hard mask layer 122A is disposed within an inner recess defined by the inner surface of the first sub-hard mask layer 120A, such that the first sub-hard mask layer 120A laterally surrounds the second sub-hard mask layer 122A. The top surfaces of the first sub-hard mask layer 120A, the second sub-hard mask layer 122A, and the second spacer 116 may be substantially coplanar. In addition, in the present embodiment, the interface between the sidewall of the second sub-hard mask layer 122A and the first sub-hard mask layer 120A can be substantially planar. Such a substantially planar interface provides improved process uniformity and dimensional control during subsequent etching and deposition steps. By minimizing irregularities at the interface, the planar configuration reduces localized stress concentrations and enhances structural integrity, thereby lowering the risk of delamination or cracking during thermal cycling or chemical mechanical polishing (CMP). Furthermore, the planar interface contributes to consistent dielectric thickness and predictable electrical characteristics around the gate structure, which improves device performance and reliability. Afterwards, the sacrificial layer 118 is removed to form a gate structure 20 of the present embodiment.

In the gate structure 20 of the present embodiment, a hard mask layer composed of the first sub-hard mask layer 120A and the second sub-hard mask layer 122A is formed on the cap layer 110A, and the second spacer 116 is disposed on the sidewall of the hard mask layer, the sidewall of the cap layer 110A and the first spacer 114. Therefore, the cap layer 110A may be effectively protected by the hard mask layer and the second spacer 116, and the first spacer 114 may also be effectively protected by the second spacer 116, so as to prevent contaminants, such as metal ions, in the subsequent processes from penetrating through the cap layer 110A or the first spacer 114 and entering the gate device 109.

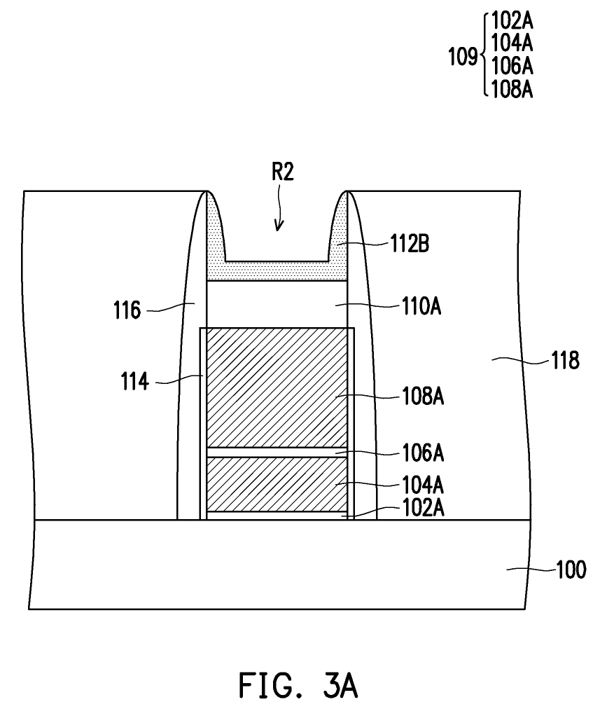

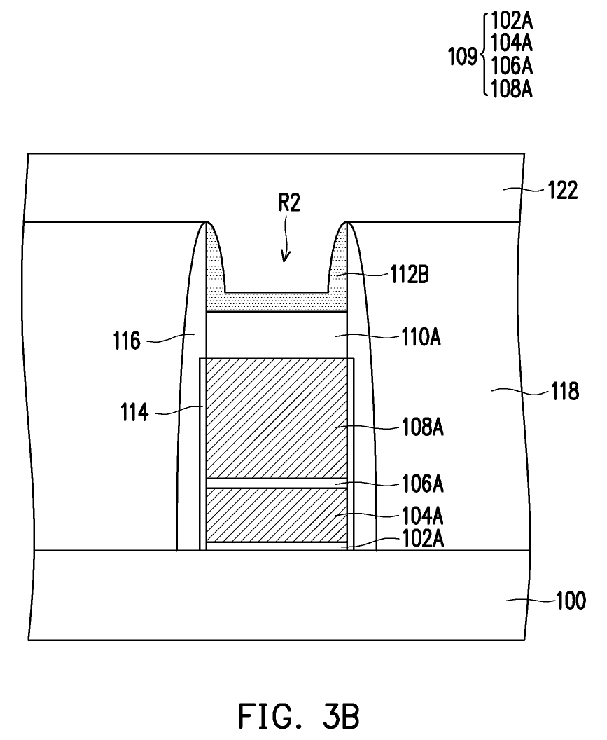

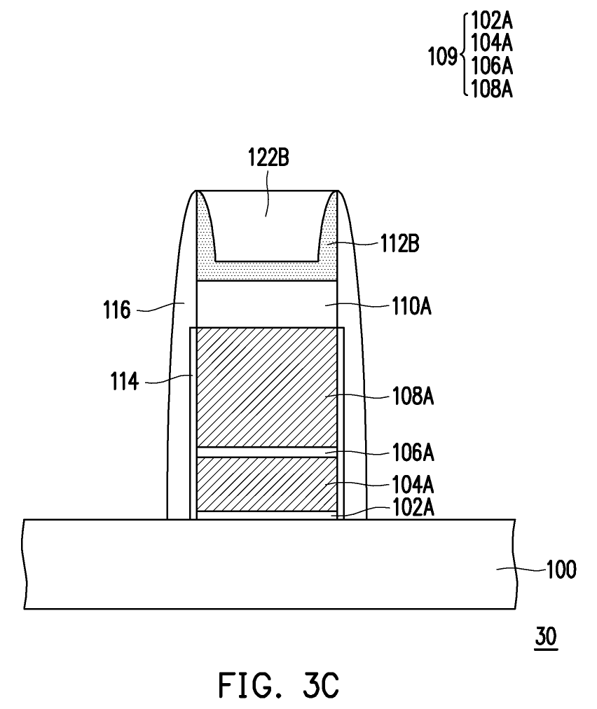

FIGS. 3A to 3C are schematic cross-sectional views of the manufacturing process of the gate structure of the third embodiment of the present invention. In the present embodiment, the same devices as in the second embodiment will be represented by the same reference symbols and will not be described again.

Referring to FIG. 3A, after a part of the sacrificial layer 118 is removed as described in FIG. 2B, a part of the hard mask layer 112A is removed to form a first sub-hard mask layer 112B having a recess R2. In the present embodiment, the recess R2 may have a curved sidewall. In the present embodiment, the first sub-hard mask layer 112B may be formed by adjusting the etching parameters during an anisotropic etching process performed on the hard mask layer 112A, but the present invention is not limited thereto. By forming the recess R2 with a curved sidewall, especially in the miniaturized device, it is helpful for subsequent filling of the second mask material layer 122 and may provide better protection for the gate device 109.

Referring to FIG. 3B, the second mask material layer 122 is formed on the first sub-hard mask layer 112B, and the second mask material layer 122 fills the recess R2.

Referring to FIG. 3C, the second mask material layer 122 outside the recess R2 is removed to form a second sub-hard mask layer 122B in the recess R2. In other words, the second sub-hard mask layer 122B is disposed within an inner recess defined by the inner surface of the first sub-hard mask layer 112B, such that the first sub-hard mask layer 120B laterally surrounds the second sub-hard mask layer 122B. The top surfaces of the first sub-hard mask layer 120B, the second sub-hard mask layer 122B, and the second spacer 116 may be substantially coplanar In addition, in the present embodiment, the interface between the sidewall of the second sub-hard mask layer 122B and the first sub-hard mask layer 112B is curved, which assists with the subsequent filling of the second mask material layer 122 and can enhance the protection of the gate device 109. Afterwards, the sacrificial layer 118 is removed to form a gate structure 30 of the present embodiment.

In the gate structure 30 of the present embodiment, a hard mask layer composed of a first sub-hard mask layer 112B and a second sub-hard mask layer 122B is formed on the cap layer 110A, and the second spacer 116 is disposed on the sidewall of the hard mask layer, the sidewall of the cap layer 110A and the first spacer 114. Therefore, the cap layer 110A may be effectively protected by the hard mask layer and the second spacer 116, and the first spacer 114 may also be effectively protected by the second spacer 116, so as to prevent contaminants, such as metal ions, in the subsequent processes from penetrating through the cap layer 110A or the first spacer 114 and entering gate device 109.

In addition, in an embodiment not shown, after forming the recess R1 as shown in FIG. 2B, the first mask material layer 120 may also be completely fills the recess R1 without forming the second mask material layer 122.

According to the above embodiments of the present invention, the unique configuration in which a hard mask layer is disposed on the cap layer, and a second spacer is disposed on a sidewall of the hard mask layer, a sidewall of the cap layer, and the first spacer, yields several unexpected and advantageous technical effects. Specifically, this arrangement provides multi-level protection for both the cap layer and the first spacer, which is not achievable in conventional structures. As a result, the issue in conventional techniques where the position of the mask pattern shifts and causes a portion of the top surface of the memory cell to be exposed can be addressed. The hard mask layer and the second spacer together form a robust barrier that effectively prevents contaminants, such as metal ions, from penetrating through the cap layer or the first spacer and entering the gate device during subsequent processing steps, thereby significantly enhancing device reliability and data retention characteristics.

Moreover, by extending the second spacer to cover the sidewalls of both the hard mask layer and the cap layer, the invention addresses the issue of word line leakage current that often arises from damage or contamination of the spacer in conventional devices, which results in improved electrical isolation and reduced leakage paths.

In addition, compared with the conventional techniques that require independently patterning the mask material layer, the method for manufacturing the gate structure of the present invention eliminates the lithography and the etching process related to this step, thereby reducing manufacturing costs and minimizing environmental impact. The enhanced protection and process simplification also enable further miniaturization of the gate structure, allowing for a higher density of dies on a wafer and contributing to lower production costs and energy consumption per integrated circuit, as well as lower energy consumption during subsequent packaging. In addition, since the reliability of the flash memory of the present invention is improved, the present invention provides a green semiconductor technology.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A gate structure, comprising:
a gate device, disposed on a substrate;
a first spacer, disposed on a sidewall of the gate device;
a cap layer, disposed on a top surface of the gate device;
a hard mask layer, disposed on the cap layer; and
a second spacer, disposed on a sidewall of the hard mask layer, a sidewall of the cap layer, and the first spacer.

2. The gate structure of claim 1, wherein a top surface of the second spacer and a top surface of the hard mask layer are coplanar.

3. The gate structure of claim 1, wherein a material of the first spacer is different from a material of the second spacer.

4. The gate structure of claim 1, wherein a material of the cap layer is different from a material of the second spacer.

5. The gate structure of claim 1, wherein a material of the hard mask layer is the same as a material of the second spacer.

6. The gate structure of claim 1, wherein the hard mask layer comprises a first sub-hard mask layer and a second sub-hard mask layer, and the second sub-hard mask layer is disposed within an inner recess defined by an inner surface of the first sub-hard mask layer.

7. The gate structure of claim 6, wherein a top surface of the second spacer, a top surface of the first sub-hard mask layer and a top surface of the second sub-hard mask layer are coplanar.

8. The gate structure of claim 6, wherein a material of the first sub-hard mask layer is different from a material of the second sub-hard mask layer, and the first sub-hard mask layer and the second spacer comprise the same material.

9. The gate structure of claim 6, wherein an interface between a sidewall of the second sub-hard mask layer and the first sub-hard mask layer is planar.

10. The gate structure of claim 6, wherein an interface between a sidewall of the second sub-hard mask layer and the first sub-hard mask layer is curved.

11. The gate structure of claim 1, wherein the gate device comprises a tunneling dielectric layer, a floating gate, an inter-gate dielectric layer and a control gate sequentially disposed on the substrate.

12. A manufacturing method of a gate structure, comprising:
forming a gate device, a cap layer and a hard mask layer sequentially on a substrate;
forming a first spacer on a sidewall of the gate device; and
forming a second spacer on a sidewall of the hard mask layer, a sidewall of the cap layer, and the first spacer.

13. The manufacturing method of claim 12, wherein a top surface of the second spacer and a top surface of the hard mask layer are coplanar.

14. The manufacturing method of claim 12, wherein after forming the second spacer, the manufacturing method further comprises:
forming a sacrificial layer on the substrate, wherein the sacrificial layer covers the second spacer and the hard mask layer;
removing a part of the sacrificial layer until a top surface of the hard mask layer is exposed;
remove the hard mask layer to form a recess;
conformally forming a first mask material layer on the sacrificial layer and in the recess;
forming a second mask material layer on the first mask material layer, wherein the second mask material layer fills the recess; and
removing the first mask material layer and the second mask material layer outside the recess to form a first sub-hard mask layer and a second sub-hard mask layer within the recess, wherein the first sub-hard mask layer is located between the second sub-hard mask layer and a sidewall and a bottom surface of the recess.

15. The manufacturing method of claim 14, wherein a top surface of the second spacer, a top surface of the first sub-hard mask layer and a top surface of the second sub-hard mask layer are coplanar.

16. The manufacturing method of claim 14, wherein an interface between a sidewall of the second sub-hard mask layer and the first sub-hard mask layer is planar.

17. The manufacturing method of claim 12, wherein after forming the second spacer, the manufacturing method further comprises:
forming a sacrificial layer on the substrate, wherein the sacrificial layer covers the second spacer and the hard mask layer;
removing a part of the sacrificial layer until a top surface of the hard mask layer is exposed;
removing a part of the hard mask layer to form a first sub-hard mask layer having a recess; and
forming a second sub-hard mask layer in the recess.

18. The manufacturing method of claim 17, wherein a method for removing the part of the hard mask layer comprises performing an anisotropic etching process.

19. The manufacturing method of claim 17, wherein an interface between a sidewall of the second sub-hard mask layer and the first sub-hard mask layer is curved.

20. The manufacturing method of claim 12, wherein the gate device comprises a tunneling dielectric layer, a floating gate, an inter-gate dielectric layer and a control gate sequentially formed on the substrate.
